(19) United States
(12) Patent Application Publication
(10) Pub. No.: US 2023/0395035 A1
(43) Pub. Date: Dec. 7, 2023

(54) GATE DRIVING CIRCUIT, DISPLAY PANEL AND DISPLAY DEVICE

(71) Applicant: HKC CORPORATION LIMITED, Shenzhen (CN)

(72) Inventors: Shangcao CAO, Shenzhen (CN); Baohong KANG, Shenzhen (CN)

(73) Assignee: HKC CORPORATION LIMITED, Shenzhen (CN)

(21) Appl. No.: 18/065,782

(22) Filed: Dec. 14, 2022

(30) Foreign Application Priority Data
Jun. 7, 2022 (CN) 202210632567.5

(51) Int. Cl. G09G 3/36

(52) U.S. Cl. CPC G09G 3/3677; G09G 2310/08

(57) ABSTRACT

Disclosed are a gate driving circuit, a display panel and a display device. The gate driving circuit applied to the display panel includes a plurality of driving groups. The display panel includes a plurality of pixel units distributed in an array and a plurality of row scanning lines for driving the pixel units. A start signal for scanning rows is sequentially received by the plurality of driving groups, and each driving group includes a plurality of gate driving units sequentially cascaded. In response that the start signal for scanning rows is received by a first level gate driving unit of each driving group, a gate driving signal is generated and output to a corresponding row scanning line and a next level gate driving unit by the first level gate driving unit of each driving group.

### CROSS-REFERENCE TO RELATED APPLICATIONS

This application claims priority to Chinese Patent Application No. 202210632567.5, filed on Jun. 7, 2022, the entire contents of which are incorporated herein by reference.

### TECHNICAL FIELD

The present disclosure relates to the technical field of displays, in particular to a gate driving circuit, a display panel and a display device.

### BACKGROUND

At present, most of the liquid crystal display panels adopt the gate driver less (GDL) technology. The GDL technology is a technology that by using the original array process of the liquid crystal display panel, a driving circuit of the horizontal scanning line is manufactured on the substrate around the display area, thereby replacing the external integrated circuit board to finish the driving of the horizontal scanning line. Through the GDL technology, the gate driver is manufactured on the array substrate of the thin film transistor, thereby reducing the cost and narrowing the product border.

With the development of high frequency and ultra-narrow border display panels, when the existing structure of the GDL circuit is in the condition of high refresh frequency (such as 120 Hz), the driving time of cascaded GDL units at all levels is reduced. Thus the signal output by GDL units at all levels becomes weaker and weaker, which makes the driving capability of the GDL circuit seriously reduced with the increase of the number of levels, and even causes circuit malfunction and abnormal pictures.

### SUMMARY

The main objective of the present disclosure is to provide a gate driving circuit, a display panel and a display device, aiming to solve a technical problem that when the gate driver less (GDL) circuit is applied to high-frequency display products, the driving capability of the GDL circuit will decline and abnormal pictures will occur.

In order to achieve the above objectives, the present disclosure provides a gate driving circuit applied to a display panel. The gate driving circuit includes a plurality of driving structures and a plurality of start timing vertical (STV) generation circuits. The display panel includes a plurality of pixel units distributed in an array and a plurality of row scanning lines for driving the pixel units. A start signal for scanning rows is sequentially received by the plurality of driving structures, and each driving structure includes a plurality of gate drivers sequentially cascaded. In response that the start signal for scanning rows is received by a first level gate driver of each driving structure, a gate driving signal is generated and output to a corresponding row scanning line and a next level gate driver by the first level gate driver of each driving structure. A controlled terminal of each STV generation circuit is for receiving a clock signal, and an output terminal of each STV generation circuit is correspondingly connected to the first level gate driver of each driving structure, the STV generation circuit being for generating the start signal for scanning rows according to the clock signal.

In an embodiment, a number of driving structures is determined according to a driving capability of the gate driving circuit.

In an embodiment, the plurality of STV generation circuits are cascaded sequentially. A first level STV generation circuit is for generating a first level start signal for scanning rows according to the clock signal and a frame on signal, and a remaining level STV generation circuit is for generating a start signal for scanning rows according to the clock signal and an upper level start signal for scanning rows output by an upper level STV generation circuit.

In an embodiment, the STV generation circuit is provided with N levels, and the N is a positive integer. A clock signal received by a 2N-1 th level STV generation circuit is a first timing signal, and another clock signal received by a 2Nth level STV generation circuit is a second timing signal, a phase difference between the first timing signal and the second timing signal being 180 degrees.

In an embodiment, the STV generation circuit includes a cascade circuit. An input terminal of the cascade circuit is for receiving an upper level start signal for scanning rows, and the cascade circuit is for generating a cascade signal according to the upper level start signal for scanning rows.

In an embodiment, the STV generation circuit further includes an output circuit. A controlled terminal of the output circuit is connected to an output terminal of the cascade circuit, a clock signal being received by an input terminal of the output circuit, and an output terminal of the output circuit is correspondingly connected to the first level gate driver of each driving structure. The output circuit is for generating a start signal for scanning rows according to the clock signal and a cascade signal, and outputting the start signal for scanning rows to a first level gate driver of a corresponding driving structure.

In an embodiment, the STV generation circuit further includes a pull-down circuit. A pull-down signal is received by a controlled terminal of the pull-down circuit, an input terminal of the pull-down circuit being respectively connected to the output terminal of the cascade circuit and the output terminal of the output circuit, and the pull-down circuit is for pulling down each of the cascade signal and the start signal for scanning rows to a low level according to the pull-down signal.

In an embodiment, the controlled terminal of the pull-down circuit is connected to an input terminal of an output circuit in a next level STV generation circuit.

In an embodiment, the cascade circuit includes a first transistor. A controlled terminal of the first transistor is connected to an input terminal of the first transistor, and a connection node between the controlled terminal and the input terminal of the first transistor is the input terminal of the cascade circuit. An output terminal of the first transistor is the output terminal of the cascade circuit.

In an embodiment, the output circuit includes a second transistor. A controlled terminal of the second transistor is the controlled terminal of the output circuit, an input terminal of the second transistor being an input terminal of the output circuit, and an output terminal of the second transistor is the output terminal of the output circuit.

In an embodiment, the second transistor is a thin film transistor. A gate of the thin film transistor is the controlled terminal of the second transistor, a source of the thin film transistor being the output terminal of the second transistor, and a drain of the thin film transistor is the input terminal of the second transistor.

In an embodiment, the output circuit further includes a first capacitor. A first terminal of the first capacitor is connected to the controlled terminal of the second transistor, and a second terminal of the first capacitor is connected to the output terminal of the second transistor.

In an embodiment, the pull-down circuit includes a third transistor, a fourth transistor, a fifth transistor and a second capacitor. A first terminal of the second capacitor is for receiving the pull-down signal, and a second terminal of the second capacitor is connected to an input terminal of the third transistor. A controlled terminal of the third transistor is connected to the output terminal of the cascade circuit, and an output terminal of the third transistor is connected to a low level. The input terminal of the third transistor is further connected to a controlled terminal of the fourth transistor, an input terminal of the fourth transistor being connected to the output terminal of the output circuit, and an output of the fourth transistor is connected to a low level. A controlled terminal of the fifth transistor is for receiving the pull-down signal, an input terminal of the fifth transistor being connected to the output terminal of the cascade circuit, and an output terminal of the fifth transistor is connected to a low level.

In order to achieve the above objectives, the present disclosure further provides a display panel including a display area and a non-display area. The display area is provided with a plurality of pixel units distributed in an array and a plurality of row scanning lines for driving the pixel units. The non-display area is provided with a gate driving circuit as mentioned above, and the gate driving circuit is for sequentially outputting a gate driving sub-signal to a corresponding row scanning line.

In order to achieve the above objectives, the present disclosure further provides a display device including a display panel and a backlight module. The display panel is provided on a light-emitting side of the backlight module, and the display panel includes a gate driving circuit as mentioned above.

In the present disclosure, the gate driving circuit is divided into a plurality of driving structures according to the driving capability of the gate driving circuit. Each driving structure includes a plurality of gate drivers cascaded sequentially. By cascading, an upper level gate driver of each driving structure may transmit the current level gate driving signal, to drive a next level gate driver to start. Correspondingly, a first level gate driver of each driving structure is connected to an output terminal of a STV generation circuit sequentially. When the driving capability of the last level gate driver in the driving structure is significantly reduced, the driving of the driving structure has been finished. The gate driving signal output by the previous group is no longer received by the first level gate driver of the next driving structure, but the start signal for scanning rows in the STV generation circuit is received and drives the first level gate driver of the next driving structure. Therefore, the driving capability of the next driving structure may be guaranteed to meet the driving requirements, and the driving capability of each gate driver of each driving structure may be guaranteed. By providing a plurality of STV generation circuits, not only the gate driving circuit can meet the requirements of display products with high refresh rate and the circuit reliability may be improved, but also the display quality of pictures may be guaranteed.

### BRIEF DESCRIPTION OF THE DRAWINGS

To illustrate the technical solutions according to the embodiments of the present disclosure or the related art more clearly, the accompanying drawings for describing the embodiments or the related art are introduced briefly in the following. Apparently, the accompanying drawings in the following description are only corresponding to some embodiments in the present disclosure. Persons of ordinary skill in the art can derive other drawings from the accompanying drawings without creative efforts.

FIG. 1 is a schematic diagram of functional modules in a gate driving circuit according to an embodiment of the present disclosure.

FIG. 2 is a schematic diagram of functional modules in the gate driving circuit according to another embodiment of the present disclosure.

FIG. 3 is a schematic timing diagram of partial circuits in a gate driving circuit according to an embodiment of the present disclosure.

FIG. 4 is a schematic structural diagram of a start timing vertical generating circuit in a gate driving circuit according to an embodiment of the present disclosure.

FIG. 5 is a schematic driving timing diagram in a gate driving circuit according to an embodiment of the present disclosure.

FIG. 6 is a schematic structural diagram of a display panel according to an embodiment of the present disclosure.

FIG. 7 is a schematic structural diagram of a display device according to an embodiment of the present disclosure.

FIG. 8 is a schematic structural diagram of a display panel according to an embodiment of the present disclosure.

FIG. 9 is a schematic structural diagram of a driving structure according to an embodiment of the present disclosure.

The realization of the objective, functional characteristics, and advantages of the present disclosure are further described with reference to the accompanying drawings.

### DETAILED DESCRIPTION OF THE EMBODIMENTS

It should be understood that the specific embodiments described herein are only used to explain the present disclosure, and are not intended to limit the present disclosure.

The technical solutions of the embodiments of the present disclosure will be described in more detail below with reference to the accompanying drawings. It is obvious that the embodiments to be described are only some rather than all of the embodiments of the present disclosure. All other embodiments obtained by persons skilled in the art based on the embodiments of the present disclosure without creative efforts shall fall within the scope of the present disclosure.

It should be noted that all the directional indications (such as up, down, left, right, front, rear . . . ) in the embodiments of the present disclosure are only used to explain the relative positional relationship, movement, or the like of the components in a certain posture (as shown in the drawings). If the specific posture changes, the directional indication will change accordingly.

Besides, the descriptions associated with, e.g., “first” and “second,” in the present disclosure are merely for descriptive purposes, and cannot be understood as indicating or suggesting relative importance or impliedly indicating the number of the indicated technical feature. Therefore, the feature associated with “first” or “second” can expressly or impliedly include at least one such feature. In addition, the technical solutions of the various embodiments can be combined with each other, but the combinations must be based on the realization of those skilled in the art. When the combination of technical solutions is contradictory or cannot be achieved, it should be considered that such a combination of technical solutions does not exist, nor does it fall within the scope of the present disclosure.

In the conventional gate driver less (GDL) driving circuit, the first level gate driver of the GDL driving circuit is usually triggered by a start timing vertical (STV) signal output by a timing controller (TCON), and a gate driving signal Gout is generated by the first level gate driver. On the one hand, the gate driving signal Gout is input to a display area of the display panel, and on the other hand, the gate driving signal Gout is used as a cascade signal, namely a trigger signal of a next level gate driver.

With the development of high-frequency and ultra-narrow border display panels, when the existing structure of the GDL circuit is under the condition of high refresh frequency, the driving capability of the GDL circuit is seriously reduced with the increase of the number of levels. When the GDL circuit is used under the condition of an ultra-narrow border, the design size for the thin film transistor (TFT) will be reduced accordingly, and the corresponding driving current and the driving capability will further be reduced. The driving capability of the GDL circuit is reduced seriously with the increase of the number of levels. Abnormal pictures and even circuit malfunction will be caused due to a reduction of the driving capability of the GDL circuit. Especially, the GDL driving technology will face greater risks when the GDL circuit is operated in a low temperature and with a high light display.

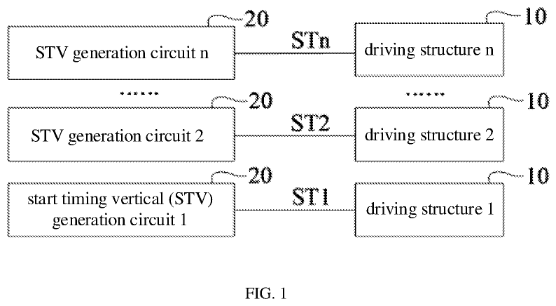

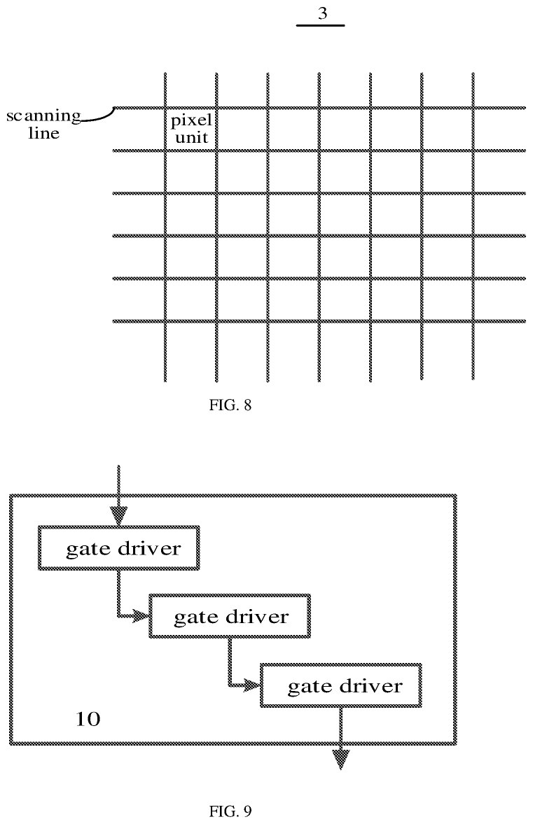

Based on the above phenomenon, the present disclosure provides a gate driving circuit, applied to a display panel 3. As shown in FIG. 8, the display panel 3 includes a plurality of pixel units distributed in an array and a plurality of row scanning lines for driving the pixel units. As shown in FIG. 1 and FIG. 9, in an embodiment, the gate driving circuit includes a plurality of driving structures 10 and a plurality of start timing vertical (STV) generation circuits. A start signal for scanning rows is sequentially received by the plurality of driving structures 10, and each driving structure 10 includes a plurality of gate drivers (not shown) sequentially cascaded. When the start signal for scanning rows is received by a first level gate driver of each driving structure 10, a gate driving signal is generated and output to a corresponding row scanning line and a next level gate driver by the first level gate driver of each driving structure 10. A controlled terminal of each STV generation circuit 20 is for receiving a clock signal, and an output terminal of each STV generation circuit 20 is correspondingly connected to the first level gate driver of each driving structure 10. The STV generation circuit 20 is for generating a start signal for scanning rows according to the clock signal.

The above gate driving circuit can be applied to a display panel 3, and the gate driving sub-signals at all levels are input to a plurality of row scanning lines by the gate drivers in the plurality of driving structures 10, to finish a driving of corresponding rows of the display panel 3.

In an embodiment, the number of driving structures 10 can be determined according to the driving capability of the gate driving circuit (such as the GDL circuit, or the gate driven on array circuit). The gate driving circuit applied to an ultra high definition (UD) product is used as an example for illustrating. The UD products have row scanning signals with 2160 levels, correspondingly, the gate driving circuit is provided with gate drivers with 2160 levels. If the driving capability of the output signal of each gate driver within 1-216 levels can be guaranteed, and the driving capability of the gate driver at 217th level starts to decline and the picture quality may be affected, the gate drivers can be divided into one driving structure 10 at every 216 levels, and the gate driving circuit for driving the UD product can be divided into 10 groups. If the driving capability of the output signal of each gate driver within 1-108 levels can be guaranteed, and the driving capability of the gate driver at 109th level starts to decline and the picture quality may be affected, the gate drivers can be divided into one driving structure 10 at every 108 levels, and the gate driving circuit for driving the UD product can be divided into 20 groups. If the driving capability of the output signal of each gate driver within 1-278 levels can be guaranteed, and the driving capability of the gate driver at 279th level starts to decline and the picture quality may be affected, the gate drivers can be divided into one driving structure 10 at every 270 levels, and the gate driving circuit for driving the UD product can be divided into 8 groups. Or in the first 7 groups, the gate drivers can be divided into one driving structure 10 at every 278 levels, and the driving structure 10 at the last level includes fewer gate drivers, which needs to be divided according to the actual situation.

The number of driving structures 10 can further be determined according to other performance of the display product, such as the number of pixel units in each partial screen of the folding screen, etc., which will not be repeated in this embodiment.

Correspondingly, the STV generation circuit 20 outputs the start signal for scanning rows ST1˜n to drive each driving structure 10, thus the driving capability of the start signal for scanning rows ST at all levels can be guaranteed. The timing of the clock signal received by each STV generation circuit 20 may be set in combination with the actual circuit, and the timing of each driving structure 10 may be combined for setting the timing of the clock signal. Each STV generation circuit 20 sequentially outputs the start signal for scanning rows at all levels to the first level gate drivers of each driving structure 10 according to the timing of the corresponding clock signal, to improve the driving capability of each driving structure 10.

Still taking the above-mentioned gate driving circuit applied to UD products and divided into 10 driving structures 10 as an example, the first level gate driver in the first driving structure 10 starts to operate when receiving the first level start signal for scanning rows ST1. The output signal of the gate drivers at the first 215 levels is not only for inputting to the corresponding row scanning lines, but also for inputting to the next level gate driver, to drive the next level gate gate driver to start. The output signal of the 216th level gate driver can effectively drive the corresponding row scanning line and the load at the back terminal. But if the 217th level gate driver is driven by the output signal of the 216th level gate driver, the driving capability of the output signal of the 217th level gate driver is hard to be guaranteed. Therefore, the 217th level gate driver is no longer driven by the output signal of the 216th level gate driver, but is driven by the start signal for scanning rows at the next level. In this way, the driving capability of the output signal of the 217th level gate driver is improved, and the driving capability of the output signals of the gate drivers within 217-432 levels driven sequentially can still be guaranteed. That is, the driving capability of the GDL circuit will be improved every 216 levels. Therefore, the driving capability of the output signal of each gate driver in each driving structure 10 can be guaranteed, to make the display of the display panel 3 stable and make the display quality excellent. Thereby guaranteeing the driving capability of the output signals of each driving structure 10 and stabilizing the display quality.

In an embodiment, the gate driving circuit is divided into a plurality of driving structures 10 according to the driving capability of the gate driving circuit. Each driving structure 10 includes a plurality of gate drivers cascaded sequentially, as shown in FIG. 9. By cascading, an upper level gate driver of each driving structure 10 may transmit the current level gate driving signal, to drive a next level gate driver to start. Correspondingly, a start signal for scanning rows is sequentially received by a plurality of the driving structures 10 according to the preset timing. When the driving capability of the last level gate driver in the driving structure 10 is significantly reduced, the driving of the driving structure 10 has been finished. The gate driving signal output by the previous group is no longer received by the first level gate driver of the next driving structure but the first level gate driver of the next driving structure 10 is driven by the start signal for scanning rows. Therefore, the driving capability of the next driving structure 10 may be guaranteed to meet the driving requirements, and the driving capability of each gate driver of each driving structure 10 may be guaranteed. In this way, not only the gate driving circuit can meet the requirements of display products with high refresh rate and the circuit reliability may be improved, but also the display quality of pictures may be guaranteed, and the requirements of display products with the high refresh rate and ultra-narrow borders may be met.

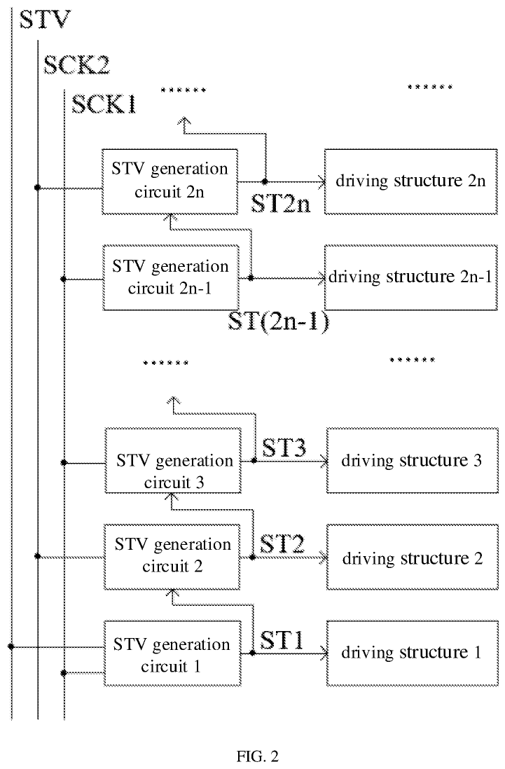

As shown in FIG. 2, in an embodiment, the plurality of STV generation circuits 20 are cascaded sequentially and a first level STV generation circuit 20 is for generating a first level start signal for scanning rows ST1 according to the clock signal and a frame on signal STY. A remaining level STV generation circuit 20 is for generating a current level start signal for scanning rows according to the clock signal and an upper level start signal for scanning rows output by an upper level STV generation circuit 20.

In an embodiment, the first level STV generation circuit 20 can receive the frame on signal STV, and output the first level start signal for scanning rows ST1 according to the corresponding first level clock signal. The first level start signal for scanning rows ST1 is not only for driving the first driving structure 10, but is also used as a start signal for the second level STV generation circuit 20. In this way, the second level STV generation circuit 20 outputs the second level start signal for scanning rows ST2 according to the first level start signal for scanning rows ST1 and the second level clock signal. The third level STV generation circuit 20 outputs the third level start signal for scanning rows ST3 according to the second level start signal for scanning rows ST2 and the third level clock signal, and so on. Therefore, according to the output signal of the STV generation circuit 20 at the previous level, the STV generation circuit 20 at the next level is controlled to start. Only one STV signal line is needed for a plurality of STV generation circuits thereby occupying a small circuit area and not affecting the width of the display panel 3.

It can be understood that the start signal for scanning rows at all levels can be output by each STV generation circuit 20 sequentially according to the frame on signal STV and the clock signal at all levels respectively. However, with the increase of the number of STV generation circuits 20, the number of introduced clock signals is grate, thus the width of the display panel 3 occupied by the clock signal lines is grate, which is not conducive to the design of narrow borders.

In an embodiment, the STV generation circuit 20 is provided with N levels, and the N is a positive integer. A clock signal received by a 2N-1th level STV generation circuits 20 is a first timing signal SCK1, and another clock signal received by a 2Nth level STV generation circuits 20 is a second timing signal SCK2. A phase difference between the first timing signal SCK1 and the second timing signal SCK2 is 180 degrees.

As shown in FIGS. 2 to 3, the odd-numbered clock signals of the first, third, and fifth levels, etc., are the first timing signals SCK1, and the even-numbered clock signals of the second, fourth, and sixth levels, etc., are the second timing signals SCK2. Specifically, as shown in FIG. 3, on the basis that the STV generation circuits 20 are cascaded and start sequentially, the first timing signal SCK1 and the second timing signal SCK2 are alternately input to the STV generation circuits 20, and the phase difference between the first timing signal SCK1 and the second timing signal SCK2 is 108 degrees. Thus the plurality of STV generation circuits 20 sequentially output the start signals for scanning rows at all levels. In this case, the STV generation circuits 20 at all levels may be driven orderly by using three signal lines of a frame on signal STV line, a first timing signal SCK1 line, and a second timing signal SCK2 line. Thus the occupied border area of signal lines can be ignored, and the driving capability of the GDL circuit may be improved without affecting the border width.

In an implementation, the main board of the display panel 3 may sequentially output a plurality of frame on signals to each driving structure 10 according to a preset timing, to improve the driving capability of each driving structure 10. In this way, the number of frame on signal lines is the same as the number of driving structures 10, which needs the main board to output the corresponding resources, that is, needs more ports of the main board. In addition, the number of the frame on signal lines is relatively large, and the occupied border area is large. The solution in present disclosure is obviously more suitable for display products with the high-frequency and narrow borders.

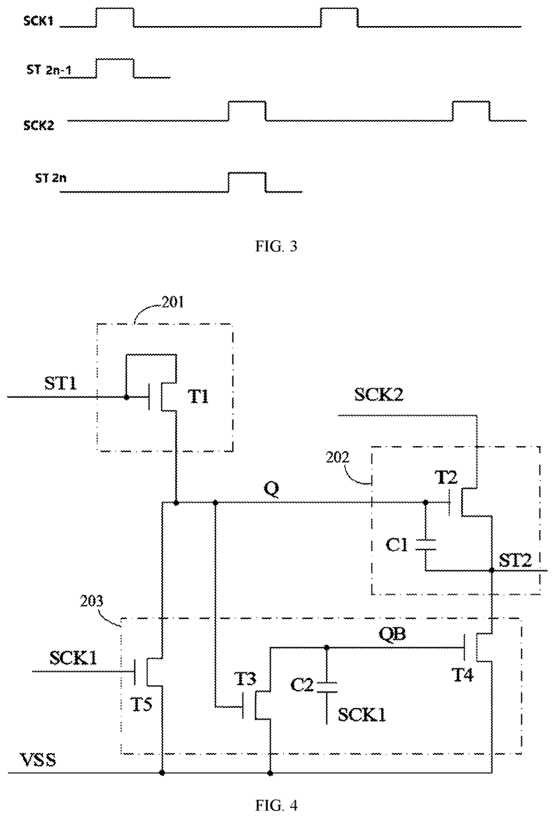

As shown in FIG. 4, in an embodiment, the STV generation circuit 20 includes a cascade circuit 201, an output circuit 202 and a pull-down circuit 203. An input terminal of the cascade circuit 201 is for receiving an upper level start signal for scanning rows, and the cascade circuit 201 is for generating a cascade signal according to the upper level start signal for scanning rows. The first level start signal for scanning rows ST1 is a flame on signal. A controlled terminal of the output circuit 202 is connected to an output terminal of the cascade circuit 201, and a clock signal is received by an input terminal of the output circuit 202, and an output terminal of the output circuit 202 is correspondingly connected to a first level gate driver of each driving structure 10. The output circuit 202 is for generating a start signal for scanning rows according to the cascade signal and the clock signal, and outputting the start signal for scanning rows to a first level gate driver of a corresponding driving structure 10.

A pull-down signal is received by a controlled terminal of the pull-down circuit 203, and an input terminal of the pull-down circuit 203 is respectively connected to an output terminal of the cascade circuit 201 and the output terminal of the output circuit 202. The pull-down circuit 203 is for pulling down the cascade signal and the start signal for scanning rows to a low level according to a pull-down signal.

After receiving an upper level start signal for scanning rows, the cascade circuit 201 is turned on and outputs a cascade signal, namely a high level signal. Then the cascade circuit 201 pulls the node Q higher to make the output circuit 202 on. After the output circuit 202 receives the corresponding clock signal, a start signal for scanning rows is generated and output to the first level gate driver in the corresponding driving structure 10.

The pull-down signal can be set according to actual requirements, for example, the start signal for scanning rows at the next level can be used as the pull-down signal at the current level. Or the clock signal received by the STV generation circuit 20 at the next level can be used as the pull-down signal received by the STV generation circuit 20 at the current level. That is, a controlled terminal of the pull-down circuit 203 is connected to the input terminal of the output circuit 202 in the STV generation circuit 20 at the next level, and the clock signal at the next level is used as the pull-down signal at the current level. Compared with the start signal for scanning rows at the next level being used as the pull-down signal at the current level, the load of the start signal for scanning rows can be reduced and the driving capability of each start signal for scanning rows can be guaranteed.

The second level STV generation circuit 20 is used as an example for illustration. After receiving the first level start signal for scanning rows ST1, the cascade circuit 201 is turned on to pre-charge the node and turn the output circuit 202 on. The second level clock signal is used as the second timing signal SCK2. When the second timing signal SCK2 with a high level is received, a second level start signal for scanning rows ST2 is output by the output circuit 202 according to the high level, to pre-charge the node in the third level STV generation circuit 20. When the first timing signal SCK1 is received, a high level is output by the output circuit 202 in the third level STV generation circuit 20, and at the same time, the pull-down circuit 203 in the second level STV generation circuit 20 operates to pull down the node and the second level start signal for scanning rows ST2 to a low level, thereby avoiding the influence of the next level clock signal on the circuit at this level. The first timing signal SCK1 and the second timing signal SCK2 are alternately used as the pull-down signals, the driving ability of the pull-down signal can be guaranteed. Compared with the start signal ST for scanning rows at the next level being used as the pull-down signal, the driving ability of the GDL circuit can be effectively improved without a reduction of the driving ability of the start signal for scanning rows.

The modules of the cascade circuit 201, the output circuit 202 and the pull-down circuit 203 can be set according to actual requirements. For example, the cascade circuit 201 includes a first transistor T1. A controlled terminal of the first transistor T1 is connected to an input terminal of the first transistor T1, and a connection node between the controlled terminal and the input terminal of the first transistor T1 is an input terminal of the cascade circuit 201. An output terminal of the first transistor T1 is the output terminal of the cascade circuit 201.

The output circuit 202 includes a second transistor T2, and a controlled terminal of the second transistor T2 is the controlled terminal of the output circuit 202. An input terminal of the second transistor T2 is an input terminal of the output circuit 202, and an output terminal of the second transistor T2 is the output terminal of the output circuit 202.

The output circuit 202 further includes a first capacitor C1, and a first terminal of the first capacitor C1 is connected to the controlled terminal of the second transistor T2, and a second terminal of the first capacitor C1 is connected to the output terminal of the second transistor T2.

The pull-down circuit 203 includes a third transistor T3, a fourth transistor T4, a fifth transistor T5 and a second capacitor C2. A first terminal of the second capacitor C2 is for receiving a pull-down signal, and a second terminal of the second capacitor C2 is connected to an input terminal of the third transistor T3. A controlled terminal of the third transistor T3 is connected to the output terminal of the cascade circuit 201, and an output terminal of the third transistor T3 is connected to a low level. The input terminal of the third transistor T3 is further connected to a controlled terminal of the fourth transistor T4, and an input terminal of the fourth transistor T4 is connected to the output terminal of the output circuit 202, and an output of the fourth transistor T4 is connected to a low level. A controlled terminal of the fifth transistor T5 is for receiving the pull-down signal, and an input terminal of the fifth transistor T5 is connected to the output terminal of the cascade circuit 201. An output terminal of the fifth transistor T5 is connected to a low level.

As shown in FIG. 4, the second level STV generation circuit 20 is used as an example for illustration. When the first transistor T1 receives the first level start signal for scanning rows ST1 (namely STV signal), the first transistor T1 is turned on and the node Q is in a high level. The third transistor T3 is turned on to pull down the node QB. The second transistor T2 is turned on to input the voltage of the second timing signal SCK2 and output the second level start signal for scanning rows ST2. In this case, the voltage of the second timing signal SCK2 is high and the second level start signal for scanning rows ST2 outputs a high level. When the high voltage of the first timing signal SCK1 is received, the fifth transistor T5 is turned on to pull down the node Q. The node QB is in a high level, and the fourth transistor T4 is turned on to pull down the second level start signal for scanning rows ST2.

It should be noted that, the above-mentioned switch tubes can be replaced by equivalent circuits or independent electronic components, which will not be repeated here. Further, the type of the above-mentioned switch tubes can further be set according to actual requirements, such as a thin film transistor. It can be understood that the gate of the thin film transistor is the controlled terminal of the switch tube, the source of the thin film transistor is the output terminal of the switch tube, and the drain of the thin film transistor is the input terminal of the switch tube.

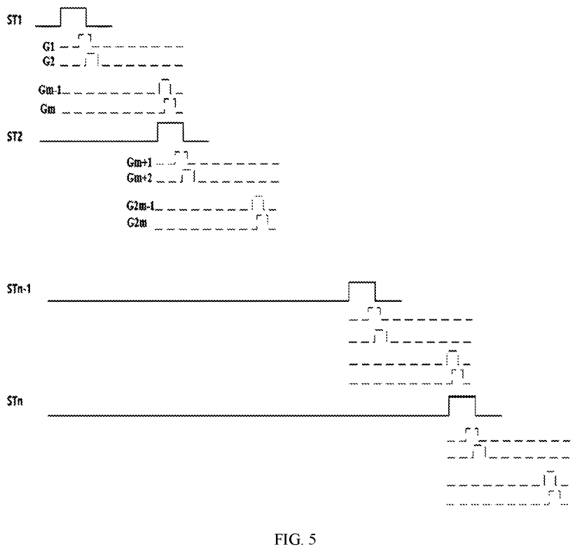

To sum up, FIG. 5 is the driving timing diagram of the gate driving circuit. The signal G is a gate driving signal for driving pixel units, and the gate driving circuit is divided into driving structures 10 with n levels. Each driving structure 10 includes gate drivers with m levels. That is, each driving structure 10 outputs gate driving signals with m levels. Correspondingly, each row scanning start signal drives gate drivers with m levels, which makes the driving capability of gate drivers with m levels strong enough to drive the corresponding pixel unit to display normally.

Based on the above circuit structure, only two signal lines of a first timing signal SCK1 line and a second timing signal SCK2 line need to be added (the STV signal line is always in the gate driving circuit). The multi-level gate drivers are correspondingly provided with a one-level STV generation circuit 20, and 5 TFTs and 2 capacitors are additionally set. Correspondingly, the circuit diagram can adopt a narrow and long panel design, thus the width of the border in the whole circuit is not increased, and the cost is very low.

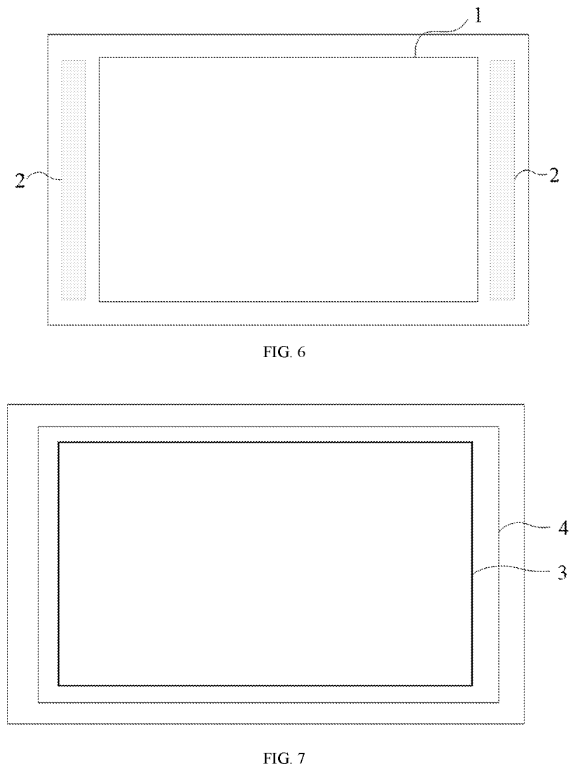

The present disclosure further provides a panel display. As shown in FIG. 6, in an embodiment, the display panel 3 includes a display area 1 and a non-display area 2. The display area 1 is provided with a plurality of pixel units distributed in an array and a plurality of row scanning lines for driving the pixel units. The non-display area 2 is provided with a gate driving circuit for sequentially outputting a gate driving sub-signal to a corresponding row scanning line. The structure of the gate driving circuit can be referred to the above-mentioned embodiments, which will not be repeated here. Of course, since the display device in the present disclosure adopts the technical solutions of the gate driving circuit mentioned above, it has at least all the beneficial effects brought by the technical solutions of the above-mentioned embodiments.

The present disclosure further provides a panel device. As shown in FIG. 7, in an embodiment, the display device includes a display panel 3 and a backlight module 4. The display panel 3 is provided on a light-emitting side of the backlight module 4, and the display panel 3 includes a gate driving circuit. The structure of the gate driving circuit can be referred to the above-mentioned embodiments, which will not be repeated here. Of course, since the display device in the present disclosure adopts all the technical solutions of the gate driving circuit mentioned above, it has at least all the beneficial effects brought by the technical solutions of the above-mentioned embodiments.

The above are only some embodiments of the present disclosure and are not to limit the scope of the present disclosure. Any equivalent structure or equivalent process transformation made by using the contents of the description and drawings of the present disclosure, directly or indirectly applied in other related technical fields, shall fall within the claimed scope of the present disclosure.

1-15. (canceled)

16. A gate driving circuit driving a display panel comprising a plurality of driving structures and a plurality of start timing vertical (STV) generation circuits, wherein:
the display panel comprises a plurality of pixel units distributed in an array and a plurality of row scanning lines for driving the plurality of pixel units,
a start signal for scanning rows of the display panel is sequentially received by the plurality of driving structures, the plurality of driving structures comprises a plurality of gate drivers sequentially cascaded, and in response to the start signal for scanning rows of the display panel is received by a first level gate driver of the plurality of driving structures, a gate driving signal is generated and outputted to a corresponding row scanning line and a next level gate driver,
a controlled terminal of the plurality of STV generation circuits receives a clock signal, and an output terminal of the plurality of STV generation circuits is correspondingly connected to the first level gate driver of the plurality of driving structures, and the plurality of STV generation circuits generate the start signal for scanning rows of the display panel according to the clock signal,
the plurality of STV generation circuits are cascaded sequentially,
a first level STV generation circuit generates a first level start signal for scanning rows of the display panel according to the clock signal and a frame on signal, and a remaining level STV generation circuit generates a start signal for scanning rows of the display panel according to the clock signal and an upper level start signal outputted by an upper level STV generation circuit,
the first level start signal for scanning rows of the display panel drives a first driving structure and is configured as a start signal for a second level STV generation circuit, and
the STV generation circuit sequentially outputs the start signal for scanning rows of the display panel to the first level gate drivers of the plurality of driving structures.

17. The gate driving circuit of claim 16, wherein a number of the plurality of driving structures is determined according to a driving capability of the gate driving circuit.

18. The gate driving circuit of claim 16, wherein a STV generation circuit is provided with N levels of gate drivers, wherein N is a positive integer, and
a clock signal received by an 2N-1th level STV generation circuit is a first timing signal, and another clock signal received by an 2Nth level STV generation circuit is a second timing signal,
wherein a phase difference between the first timing signal and the second timing signal is 180 degrees.

19. The gate driving circuit of claim 18, wherein the STV generation circuit comprises a cascade circuit, and
an input terminal of the cascade circuit receives an upper level start signal for scanning rows of the display panel, and the cascade circuit generates a cascade signal according to the upper level start signal for scanning rows of the display panel.

20. The gate driving circuit of claim 19, wherein the STV generation circuit comprises an output circuit,
a controlled terminal of the output circuit is connected to an output terminal of the cascade circuit, a clock signal is received by an input terminal of the output circuit, and an output terminal of the output circuit is correspondingly connected to the first level gate driver of the plurality of driving structures, and
the output circuit generates a start signal for scanning rows of the display panel according to the clock signal and a cascade signal, and outputs the start signal for scanning rows to a first level gate driver of a corresponding driving structure.

21. The gate driving circuit of claim 20, wherein the STV generation circuit comprises a pull-down circuit,
a pull-down signal is received by a controlled terminal of the pull-down circuit, an input terminal of the pull-down circuit is respectively connected to the output terminal of the cascade circuit and the output terminal of the output circuit, and the pull-down circuit pulls down the cascade signal and the start signal for scanning rows of the display panel to a low level according to the pull-down signal.

22. The gate driving circuit of claim 21, wherein the controlled terminal of the pull-down circuit is connected to an input terminal of an output circuit in a next level STV generation circuit.

23. The gate driving circuit of claim 21, wherein the cascade circuit comprises a first transistor,
a controlled terminal of the first transistor is connected to an input terminal of the first transistor, and a connection node between the controlled terminal and the input terminal of the first transistor is the input terminal of the cascade circuit, and
an output terminal of the first transistor is the output terminal of the cascade circuit.

24. The gate driving circuit of claim 21, wherein the output circuit comprises a second transistor, and
a controlled terminal of the second transistor is the controlled terminal of the output circuit, an input terminal of the second transistor is an input terminal of the output circuit, and an output terminal of the second transistor is the output terminal of the output circuit.

25. The gate driving circuit of claim 24, wherein the second transistor is a thin film transistor, and
a gate of the thin film transistor is the controlled terminal of the thin film transistor, a source of the thin film transistor is the output terminal of the thin film transistor, and a drain of the thin film transistor is the input terminal of the thin film transistor.

26. The gate driving circuit of claim 24, wherein the output circuit further comprises a first capacitor, and
a first terminal of the first capacitor is connected to the controlled terminal of the second transistor, and a second terminal of the first capacitor is connected to the output terminal of the second transistor.

27. The gate driving circuit of claim 21, wherein the pull-down circuit comprises a third transistor, a fourth transistor, a fifth transistor and a second capacitor,
a first terminal of the second capacitor receives the pull-down signal, and a second terminal of the second capacitor is connected to an input terminal of the third transistor,
a controlled terminal of the third transistor is connected to the output terminal of the cascade circuit, and an output terminal of the third transistor is connected to a low level,
the input terminal of the third transistor is further connected to a controlled terminal of the fourth transistor, an input terminal of the fourth transistor is connected to the output terminal of the output circuit, and an output of the fourth transistor is connected to the low level, and
a controlled terminal of the fifth transistor is for receiving the pull-down signal, an input terminal of the fifth transistor is connected to the output terminal of the cascade circuit, and an output terminal of the fifth transistor is connected to a low level.

28. A display panel comprising a display area and a non-display area, wherein the display area is provided with a plurality of pixel units distributed in an array and a plurality of row scanning lines for driving the plurality of pixel units,
the non-display area being provided with a gate driving circuit driving a display panel, the gate driving circuit comprising a plurality of driving structures and a plurality of start timing vertical (STV) generation circuits,
the display panel comprises the plurality of pixel units distributed in the array and the plurality of row scanning lines for driving the plurality of pixel units,
a start signal for scanning rows of the display panel is sequentially received by the plurality of driving structures, the plurality of driving structures comprise a plurality of gate drivers sequentially cascaded, an upper level gate driver of the plurality of driving structures transmits a current level gate driving signal to drive a next level gate driver to start, and in response to that the start signal for scanning rows of the display panel is received by a first level gate driver of the plurality of driving structures, a gate driving signal is generated and outputted to a corresponding row scanning line and a next level gate driver,
a controlled terminal of the plurality of STV generation circuits receives a clock signal, and an output terminal of the plurality of STV generation circuits is correspondingly connected to the first level gate driver of the plurality of driving structures, the plurality of STV generation circuits generate the start signal for scanning rows of the display panel according to the clock signal,
the plurality of STV generation circuits are cascaded sequentially,
a first level STV generation circuit generates a first level start signal for scanning rows of the display panel according to the clock signal and a frame on signal, and a remaining level STV generation circuit generates a start signal for scanning rows of the display panel according to the clock signal and an upper level start signal outputted by an upper level STV generation circuit.
the first level start signal for scanning rows of the display panel drives a first driving structure and is configured as a start signal for a second level STV generation circuit,
the gate driving circuit sequentially outputs a gate driving sub-signal to a corresponding row scanning line, and
the STV generation circuit sequentially outputs the start signal for scanning rows of the display panel to the first level gate drivers of the plurality of driving structures.

29. A display device, comprising a display panel and a backlight module, wherein the display panel is arranged on a light-emitting side of the backlight module,
the display panel comprises a gate driving circuit driving the display panel, the gate driving circuit comprising a plurality of driving structures and a plurality of start timing vertical (STV) generation circuits,
the display panel comprises a plurality of pixel units distributed in an array and a plurality of row scanning lines for driving the plurality of pixel units,
a start signal for scanning rows of the display panel is sequentially received by the plurality of driving structures, the plurality of driving structures comprise a plurality of gate drivers sequentially cascaded, an upper level gate driver of the plurality of driving structures transmits a current level gate driving signal to drive a next level gate driver to start, and in response to that the start signal for scanning rows of the display panel is received by a first level gate driver of the plurality of driving structures, a gate driving signal is generated and outputted to a corresponding row scanning line and a next level gate driver,
a controlled terminal of the plurality of STV generation circuits receives a clock signal, and an output terminal of the plurality of STV generation circuits is correspondingly connected to the first level gate driver of the plurality of driving structures, the plurality of STV generation circuits generate the start signal for scanning rows of the display panel according to the clock signal,
the plurality of STV generation circuits are cascaded sequentially,
a first level STV generation circuit generates a first level start signal for scanning rows of the display panel according to the clock signal and a frame on signal, and a remaining level STV generation circuit generates a start signal for scanning rows of the display panel according to the clock signal and an upper level start signal outputted by an upper level STV generation circuit.
the first level start signal for scanning rows of the display panel drives a first driving structure and is configured as a start signal for a second level STV generation circuit,
the gate driving circuit sequentially outputs a gate driving sub-signal to a corresponding row scanning line, and
the STV generation circuit sequentially outputs the start signal for scanning rows of the display panel to the first level gate drivers of the plurality of driving structures.
